(19) United States
(12) Patent Application Publication
(10) Pub. No.: US 2019/0271740 A1
(43) Pub. Date: Sep. 5, 2019

(54) NON-INTRUSIVE ON-CHIP DEBUGGER WITH REMOTE PROTOCOL SUPPORT

(71) Applicant: CHANGYI GU, SAN DIEGO, CA (US)

(72) Inventor: CHANGYI GU, SAN DIEGO, CA (US)

(21) Appl. No.: 15/911,178

(22) Filed: Mar. 5, 2018

(51) Int. Cl. G01R 31/317; G01R 31/3177

(52) U.S. Cl. CPC G01R 31/31705; G01R 31/3177

(57) ABSTRACT

A method and apparatus for non-intrusive on-chip debugging is disclosed. The method and apparatus also support remote protocol to directly communicate with a host machine running a debugger software, without any additional debug controllers in between. And scan-chain is not required for said method and apparatus.

### CROSS-REFERENCE TO RELATED APPLICATIONS

Not Applicable

### FIELD OF THE INVENTION

This disclosure generally relates to software debugging using additional hardware.

### BACKGROUND

As the size and complexity of software grows, debugging the software becomes a difficult task. Such difficulty is more acute for the bare-metal application software, where there is no underling support from the operating systems. And for many embedded systems, being able to support remote protocol for debug is also preferred.

In the past, some attempted to overcome this difficulty by integrating software debug modules (such as GDB stub) with the application software. The software debug module will communicate with a debugger software (such as GDB) running on a host PC for data and control. Although this solution does not require the assistance of additional hardware, it is intrusive to the application software as both the application software and the software debug module have to be executed on the same processor core.

Others explored the scheme of using a scan-chain based debugger. One of such debuggers is illustrated in FIG. 2. In such scheme, a debugger controller 210 external to the SoC chip 240 is used. And another piece of software called debugger server 211 (such as GDB server) is being executed on the debug controller 210. The debugger server 211 communicates with the debugger software 231 (such as GDB) through a standard remote protocol 220, and it then extracts the control and data from the remote protocol packets, and translates them into JTAG operations to operate the scan-chain 241. Such solution is not intrusive to the application software 242, but it requires a debug controller 210 external to the SoC chip 240. And the processor core 243 has to support scan-chain as well.

### SUMMARY OF THE INVENTION

This disclosure presents a method and apparatus for on-chip debugger. The on-chip debugger is able to debug the application software in a non-intrusive way. It does not use scan-chain, nor does it require external debug controller to function. Instead it can communicate with the debugger software (such as GDB) directly through standard remote protocol for control and data.

To achieve the objects aforementioned, this disclosure proposes to have the memory or register files shared between the processor core and the on-chip debugger. At any given time, only one of the entities (processor core or on-chip debugger) can access the memory or register files. When the processor core is in active state, the memory or register files are accessed by the process core. When the processor core is in Pause state, the access to memory or register files will be switched to the on-chip debugger.

This disclosure also proposes to have the processor core expose its internal Run/Pause state as an output signal, which is hard-wired to the on-chip debugger. To run/pause the process core, the process core also accepts a Run/Pause signal as input, which is directly toggled by the on-chip debugger.

If hardware breakpoint needs to be supported, the processor core will also expose dedicated input ports for addresses of hardware breakpoints. Accordingly, the on-chip debugger will have dedicated output ports for those addresses.

To make the debugging non-intrusive, the on-chip debugger does not expose any registers to the process core, and it does not rely on any debug messages from the processor core to function either.

To fit the on-chip debugger with the above signals and structures, and to make the on-chip debugger function without external debug controller, this disclosure proposes to have the on-chip debugger made of logic modules (Flip-Flops and combinational logic only). These logic modules comprise Physical Interface Module, Debug Protocol Module and Debug Control/Status Module. In the preferred embodiment of the on-chip debugger, the only place where memory cell is used is the packet buffer, which stores the remote protocol packets.

The logic modules in the on-chip debugger all contain their own Finite State Machines for internal control. There is no software being executed inside the on-chip debugger. In other words, the on-chip debugger does not contain any functional blocks for instruction-fetch, instruction-decode or instruction-execution. Nor does it contain any instruction memory.

### BRIEF DESCRIPTION OF DRAWINGS

This disclosure may be better understood with the assistance of the following description, taken in conjunction with the accompanying drawings, in which:

FIG. 1 is a block diagram of an exemplary embodiment of the proposed non-intrusive on-chip debugger. It does not use scan-chain. Nor does it rely on any external debug controllers to function.

FIG. 2 illustrates an example of scan-chain based debugger, which requires an external debug controller to function.

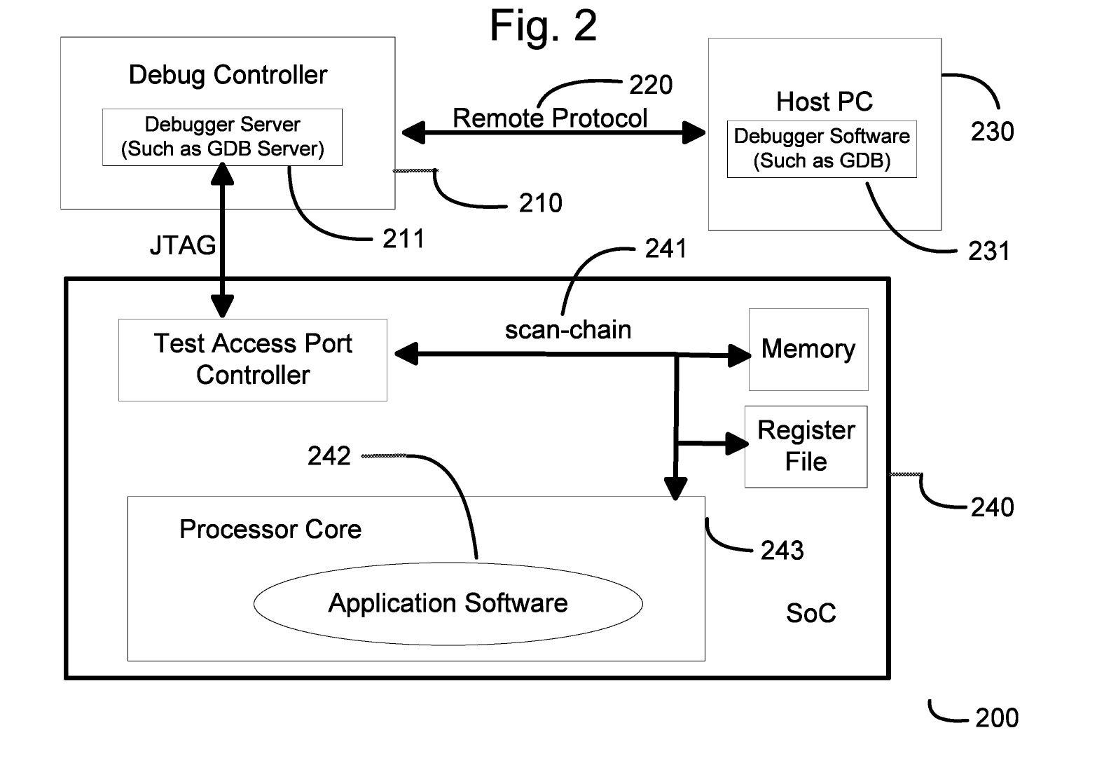

FIG. 3 illustrates the on-chip debugger from the standpoint of OSI model.

FIG. 4 shows the FSM (Finite State Machine) inside the preferred embodiment of the Physical Interface Module.

FIG. 5 shows the FSM (Finite State Machine) for packet-receiving inside the Debug Protocol Module.

### DETAILED DESCRIPTION

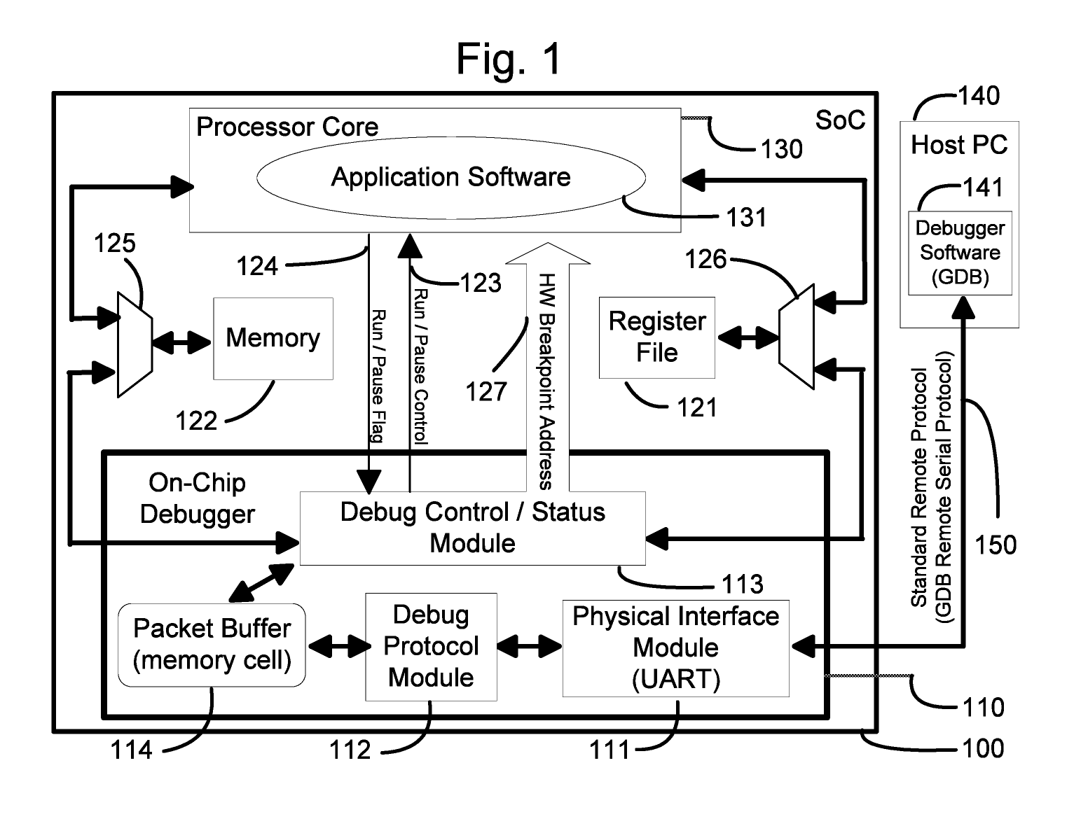

As will be appreciated by persons of skill in the art, this disclosure may be embodied as a method or an apparatus of an on-chip debugger in SoC chips. FIG. 1 is an example of the preferred embodiment of the on-chip debugger 110. The on-chip debugger 110 comprises 3 logic modules made of Flip-Flops and combinational logics: Physical Interface Module 111, Debug Protocol Module 112 and Debug Control/Status Module 113. The on-chip debugger 110 also contains a Packet Buffer 114.

The on-chip debugger 110 in FIG. 1 will communicate with a debugger software 141 that runs on a host PC 140. Such communication is carried out directly through standard remote protocol 150, with no external debug controllers in between. For the preferred embodiment, the preferred debugger software 141 is GNU Debugger (GDB), and the standard remote protocol 150 is GDB Remote Serial Protocol accordingly. The debug control information is wrapped in the packets of GDB Remote Serial Protocol 150, and is sent by the GDB 141 to the on-chip debugger 110, extracted by the Debug Protocol Module 112, and saved in the Packet Buffer 114. The Debug Control/Status Module 113 will get those information from the Packet Buffer 114, and act upon them. Conversely, if status information is requested by the GDB 141, the Debug Control/Status Module 113 will collect the status from the processor core 130, or read data from Memory 122 or Register File 121. The Debug Protocol Module 112 will then wrap the status as a packet of GDB Remote Serial Protocol 150, and send the packet to the GDB 141. For the preferred embodiment, the Packet Buffer 114 is implemented as a dual port memory. And it is the only module made with memory cells in the on-chip debugger 110.

The preferred embodiment in FIG. 1 has the memory 122 and register file 121 both shared between the on-chip debugger 110 and the processor core 130. There are two arbiters 125 and 126 that determine which entity (processor core 130/on-chip debugger 110) will have access to the memory 122 or register file 121. In the preferred embodiment, the processor core 130 always has the higher priority over the on-chip debugger 110 for memory 122 and register file 121 access.

To work with the on-chip debugger 110, the processor core 130 in FIG. 1 has its internal Run/Pause state exposed as a level signal 124, with one logic level for Run state, and the opposite logic level for Pause state. This level signal 124 is an output port on the processor core 130 side, and an input port to the Debugger Control/Status Module 113 on the on-chip debugger 110 side. Conversely, the Run/Pause state of the processor core 130 can be switched by an edge signal 123. To switch the state of the processor core 130, the on-chip debugger 110 can toggle the signal 123, and a rising edge or a falling edge of the signal 123 will make the processor core 130 switch to its opposite state.

In FIG. 1, there are two ways that can make the processor core 130 switch from Run state to Pause state. One is to let the on-chip debugger 110 toggle the signal 123, which will force the processor core 130 into Pause state. The other is to let the processor core 130 execute a BREAK instruction or hit on a hardware breakpoint. For the preferred embodiment, the BREAK instruction is actually part of the processor core's instruction set.

The on-chip debugger 110 in FIG. 1 is non-intrusive, as the application software 131 is the only software being executed by the processor core 130. And the on-chip debugger 110 does not expose any debug registers to the process core 130, nor does it rely on any debug message from the processor core 130 to function.

The debugger software 141 in FIG. 1 will send packets to the on-chip debugger 110 to run/pause the processor core 130, read/write memory 122, or read/write register file 121. And these packets are defined by the Standard Remote Protocol 150. For the preferred embodiment, the debugger software 141 is chosen to be GNU Debugger (GDB), and the on-chip debugger 110 supports the packets of GDB Remote Serial Protocol comprising:
type ‘?’ for halt reason;
type ‘m’ for memory read;
type ‘X’ for memory write;
type ‘g’ for register file dump;
type ‘p’ for single register read;
type ‘P’ for single register write;
type ‘Z’ for adding hardware breakpoint;
type ‘z’ for removing hardware breakpoint;
type ‘s’ for single step;
type ‘c’ for continuing execution.

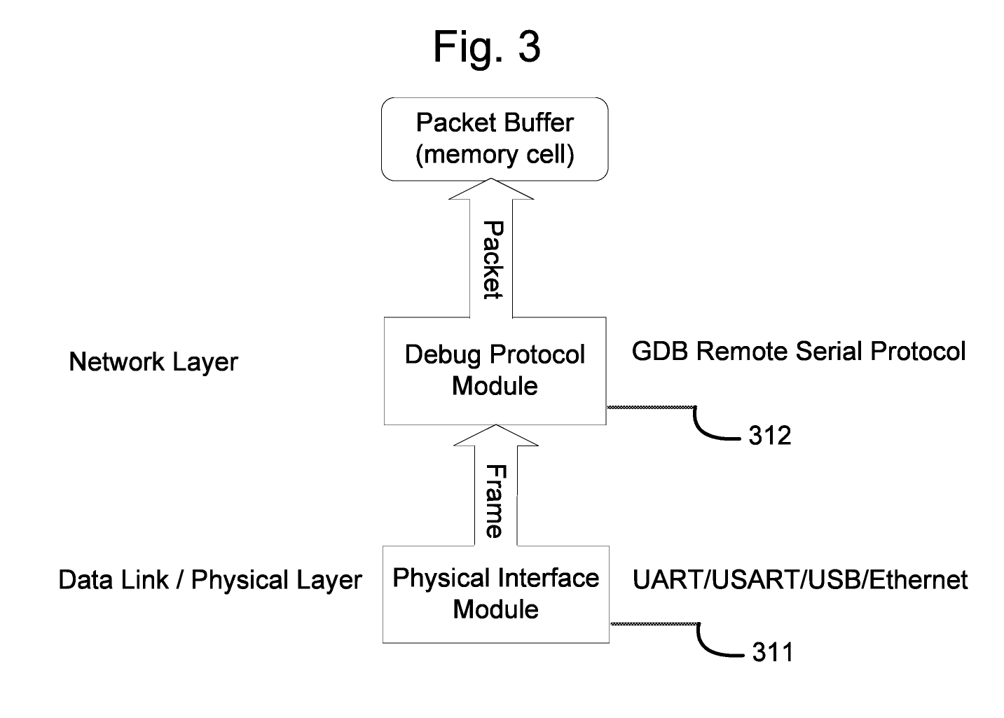

For the preferred embodiment in FIG. 1, those packets mentioned above are sent by the GDB 141 to the on-chip debugger 110 through a data-link/physical layer interface. And the data-link/physical layer is handled by the Physical Interface Module 111. After passing through the data-link/physical layer, those GDB Remote Serial Protocol packets are further processed by the Debug Protocol Module 112, which will extract the payload and save it in the Packet Buffer 114. And the relationship between Debug Protocol Module 112 and Physical Interface Module 111 is further explained in FIG. 3.

As illustrated in FIG. 3, from the standpoint of OSI model, the Physical Interface Module 311 can be mapped to OSI Physical Layer and Data Link Linker, while the Debug Protocol Module 312 can be mapped to OSI Network Layer. For the preferred embodiment, the Physical Interface Module 311 works on UART/RS232 frames, while the Debug Protocol Module 312 works on the granularity of packets for GDB Remote Serial Protocol. For alternative embodiments, the Physical Interface Module 311 can also work on USB frames or Ethernet frames, while the Debug Protocol Module 312 can work on some other forms of remote debug protocols.

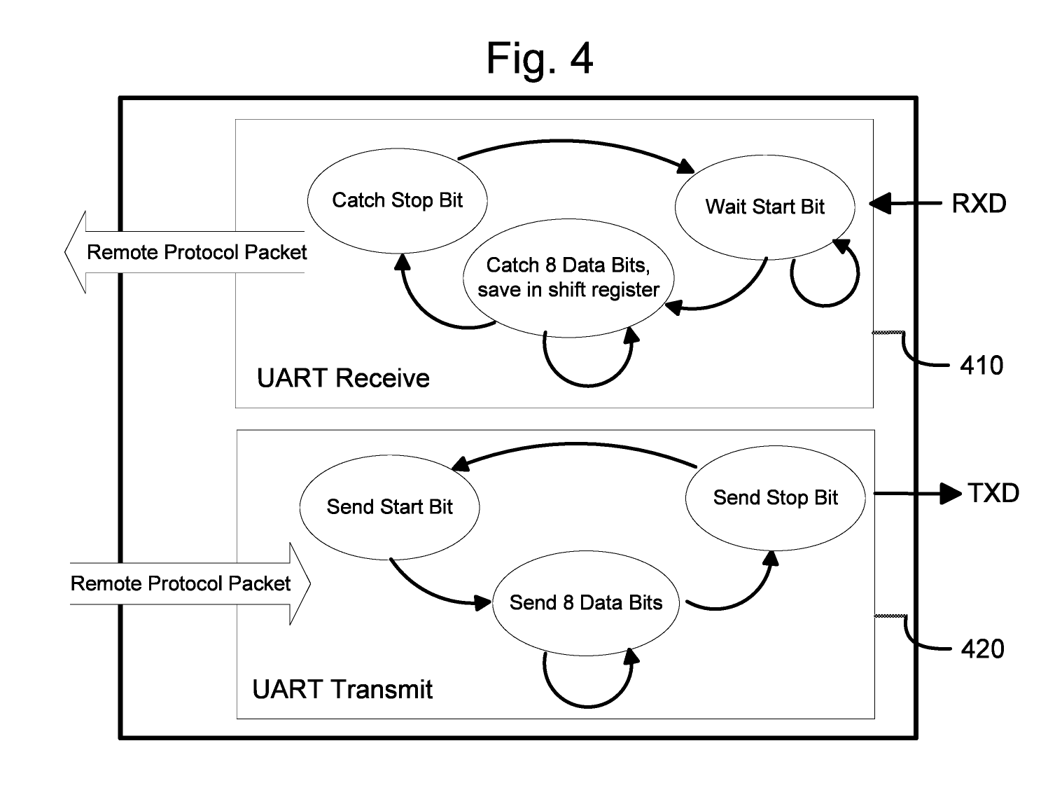

The Physical Interface Module 111 for the preferred embodiment in FIG. 1 is further explained by FIG. 4, for which the UART/RS232 frame format is supported. For the preferred UART/RS232 frame format, it is configured to have 1 start bit, 8 data bits, 1 stop bit and zero parity bits. The Physical Interface Module can be divided into two sub-blocks for Receive 410 and Transmit 420 each, both are made with Flip-Flops and combinational logics only. The Receive sub-block 410 has 3 states in its FSM (Finite State Machine) for the start bit, data bits and stop bit respectively, so does the Transmit sub-block 420. For the UART/RS232 frames, the payload is one byte per frame. And those bytes will be exchanged with the Debug Protocol Module 112 in FIG. 1.

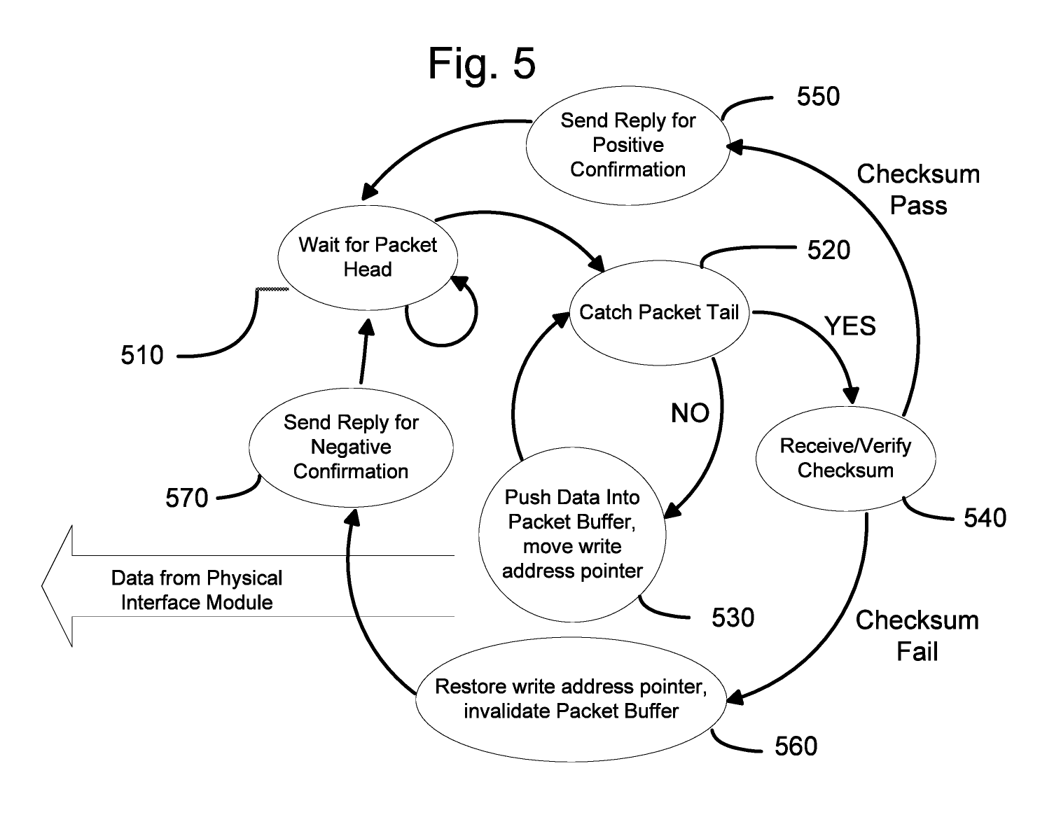

The Debug Protocol Module 112 for the preferred embodiment in FIG. 1 is further explained by FIG. 5, for which the packets of GDB Remote Serial Protocol are processed. The preferred packet format comprises a head character, payload, a tail character and checksum. The Debug Protocol Module is also made only with Flip-Flops and combinational logics. The correspondent FSM for receiving is illustrated in FIG. 5.

In FIG. 5 where a packet of GDB Remote Serial Protocol is being received, the FSM starts out by looking for the head character in state 510. When the head character is located, the state will turn into 520 to look for the tail character. If the next incoming character is not the tail character, state 530 will become active, the received non-tail character will be pushed into the Packet Buffer (114 in FIG. 1), and write address will be moved accordingly. The active state will then become 520 again. The back-and-forth between state 520 and 530 will carry on until a tail character is identified, by which the active state will become 540 to receive and verify the checksum. If checksum is passed, a positive confirmation will be sent back to the debugger software (GDB) in state 550, and the whole FSM will start over again from state 510. Otherwise, if checksum fails, state 560 will restore the write address pointer and invalidate the packet buffer. A negative confirmation will then be sent out before moving back to state 510 to receive a new packet.

The Debug Control/Status module 113 in FIG. 1 will respond based on the packets received. For the preferred embodiment where GDB Remote Serial Protocol is used, the Debug Control/Status module 113 will respond based on the packet type.

For GDB Remote Serial Protocol—packet type ‘?’, where the halt reason is requested by GDB, the Debug Control/Status module 113 in FIG. 1 will reply signal number 5 (SIGTRAP).

For GDB Remote Serial Protocol—packet type ‘m’, a memory read will be initiated by the Debug Control/Status module 113 in FIG. 1. And the data obtained will be sent back to the GDB with each byte as a two-digit hex number.

For GDB Remote Serial Protocol—packet type ‘X’, the Debug Control/Status module 113 in FIG. 1 will extract the binary data from the packet payload, and write them to the memory. A reply of ‘OK’ will also be sent back to the GDB under normal circumstances.

For GDB Remote Serial Protocol—packet type ‘g’, the Debug Control/Status module 113 in FIG. 1 will read out all the register values (including the Program Counter) from the register file, and send them back with each byte as a two-digit hex number.

For GDB Remote Serial Protocol—packet type ‘p’, a single register read will be initiated by the Debug Control/Status module 113 in FIG. 1. And the data obtained will be sent back to the GDB with each byte as a two-digit hex number.

For GDB Remote Serial Protocol—packet type ‘P’, a single register write will be initiated by the Debug Control/Status module 113 in FIG. 1. And a reply of ‘OK’ will be sent back to the GDB under normal circumstances.

For GDB Remote Serial Protocol—packet type ‘Z’ or ‘z’, where hardware breakpoint is added or removed, the Debug Control/Status module 113 in FIG. 1 will use the dedicated port of HW Breakpoint Address 127 to enable or disable hardware breakpoints. And a reply of ‘OK’ will be sent back to the GDB under normal circumstances.

For GDB Remote Serial Protocol—packet type ‘c’, the Debug Control/Status module 113 in FIG. 1 will toggle the Run/Pause Control signal 123 to switch the processor core back to Run state. It will then keep monitoring the Run/Pause Flag 124 until the processor core 130 executes a BREAK instruction or hit on a hardware breakpoint, and becomes paused again. A signal number 5 (SIGTRAP) will be sent back to the GDB when the processor core 130 re-enters the Pause state.

For GDB Remote Serial Protocol—packet type ‘s’, the Debug Control/Status module 113 in FIG. 1 will toggle the Run/Pause Control signal 123, keep the new signal level for only one clock cycle, and then toggle it back again. Accordingly, the processor core 130 will execute only one instruction before it re-enters the Pause state. And A signal number 5 (SIGTRAP) will be sent back to the GDB afterwards.

In addition to the preferred embodiment mentioned above, the disclosure could also have other forms of alternative embodiment.

In one alternative embodiment, the two arbitrators 125 and 126 in FIG. 1 are replaced with two multiplexers, and these multiplexers are controlled by the on-chip debugger 110 through additional signals.

In one alternative embodiment, the register file 121 in FIG. 1 is moved into the processor core 130. When the processor core 130 executes a BREAK instruction or hit on a hardware breakpoint, it will dump all the register values into a predetermined region in memory 122 before it enters the Pause state.

In one alternative embodiment, additional memory cells might be used inside the Physical Interface Module 111 in FIG. 1 as FIFO.

In one alternative embodiment, the Physical Interface Module 111 in FIG. 1 will support USB interface instead of UART. And when USB interface is supported, additional memory cells might be used inside the Physical Interface Module 111.

In one alternative embodiment, the Physical Interface Module 111 in FIG. 1 will support Ethernet interface instead of UART. And when Ethernet interface is supported, additional memory cells might be used inside the Physical Interface Module 111.

In one alternative embodiment, a UART/USB bridge external to the on-chip debugger 110 in FIG. 1 is used to covert between UART frames and USB frames.

In one alternative embodiment, a UART/Ethernet bridge external to the on-chip debugger 110 in FIG. 1 is used to covert between UART frames and Ethernet frames.

What is claimed is:

1. An on-chip debugger apparatus comprising:
an on-chip physical interface module that sends/receives frames in the format of UART/RS232 protocol;
an on-chip debug protocol module that sends/receives packets in the format of GDB Remote Serial Protocol, and said debug protocol module consists of Flip-Flops and combinational logics only, which does not contain any sub-units for software instruction fetch or software instruction execution;
an on-chip packet buffer to store the payload portion of the command packets for GDB Remote Serial Protocol;
an on-chip debug control/status module that responds based on the packets received, and said debug control/status module consists of Flip-Flops and combinational logics only, which does not contain any sub-units for software instruction fetch or software instruction execution, nor does it rely on scan-chains to function, and said debug control/status module only responds to a subset of commands in GDB Remote Serial Protocol;

2. (canceled)

3. (canceled)

4. The on-chip debugger apparatus as in claim 1, wherein the subset of the commands in GDB Remote Serial Protocol comprising:
type ‘?’ for halt reason;
type ‘m’ for memory read;
type ‘X’ for memory write;
type ‘g’ for register file dump;
type ‘p’ for single register read;
type ‘P’ for single register write;
type ‘Z’ for adding hardware breakpoint;
type ‘z’ for removing hardware breakpoint;
type ‘s’ for single step;
type ‘c’ for continuing execution.

5. (canceled)

6. (canceled)

7. (canceled)

8. (canceled)

9. The on-chip debugger apparatus as in claim 1, wherein said on-chip debugger has a dedicated output port for run/pause control, and a dedicated input port for run/pause flag.

10. The on-chip debugger apparatus as in claim 1, wherein said on-chip debugger has a dedicated output port for hardware breakpoint address.

11. A method of debugging software using additional hardware comprising:
receiving frames in the format of UART/RS232 protocol from a host machine that runs GNU Debugger;
without fetching or executing software instructions, extracting packets of GNU Remote Serial Protocol from said UART/RS232 frames with Flip-Flops and combinational logics only;
saving the payload of said packets of GNU Remote Protocol in a buffer;
without using scan-chain, performing control actions and preparing reply packets only for a subset of commands in GNU Remote Serial Protocol;
without fetching or executing software instructions, sending the reply packets using the UART/RS232 Protocol with Flip-Flops and combinational logics only.

12. (canceled)

13. (canceled)

14. The method of claim 11, wherein the subset of commands in GNU Remote Protocol further comprising:
type ‘?’ for halt reason;
type ‘m’ for memory read;
type ‘X’ for memory write;
type ‘g’ for register file dump;
type ‘p’ for single register read;
type ‘P’ for single register write;
type ‘Z’ for adding hardware breakpoint;
type ‘z’ for removing hardware breakpoint;
type ‘s’ for single step;
type ‘c’ for continuing execution.

15. (canceled)

16. (canceled)

17. (canceled)

18. (canceled)

19. The method of claim 11, wherein the performing control action step further comprises sub-steps of using a dedicated output port for Run/Pause control, and a dedicated input port for Run/Pause flag.

20. The method of claim 11, wherein the performing control action step further comprises sub-steps of using a dedicated output port for hardware breakpoint address.
